(19) United States
(12) Patent Application Publication
(10) Pub. No.: US 2015/0219798 A1
(43) Pub. Date: Aug. 6, 2015

(54) OPTICAL MEMBER WITH ANTIREFLECTION FILM, AND METHOD OF MANUFACTURING THE SAME

(71) Applicant: FUJIFILM Corporation, Tokyo (JP)

(72) Inventors: Shinichiro SONODA, Ashigarakami-gun (JP); Shinya HAKUTA, Ashigarakami-gun (JP)

(73) Assignee: FUJIFILM Corporation, Tokyo (JP)

(21) Appl. No.: 14/686,309

(22) Filed: Apr. 14, 2015

Related U.S. Application Data
(63) Continuation of application No. PCT/JP2013/006048, filed on Oct. 10, 2013.

(30) Foreign Application Priority Data
Oct. 17, 2012 (JP) 2012-229873

(51) Int. Cl. G02B 1/11; C23C 14/00

(52) U.S. Cl. CPC G02B 1/11; C23C 14/0036

(57) ABSTRACT

An antireflection film including a transparent thin film layer, and a transparent fine uneven layer whose main component is an alumina hydrate, which layers are formed in this order on a surface of a transparent substrate, is provided. The transparent thin film layer has an intermediate refractive index between the refractive index of the transparent substrate and the refractive index of the fine uneven layer, and the transparent thin film layer includes at least a nitride layer or an oxynitride layer.

### CROSS-REFERENCE TO RELATED APPLICATIONS

This application is a Continuation of PCT International Application No. PCT/JP2013/006048 filed on Oct. 10, 2013, which claims priority under 35 U.S.C. §119(a) to Japanese Patent Application No. 2012-229873 filed on Oct. 17, 2012. Each of the above applications is hereby expressly incorporated by reference, in its entirety, into the present application.

### BACKGROUND OF THE INVENTION

1. Field of the Invention

The present invention relates to an optical member and a method of manufacturing the optical member, and in particular to an optical member provided with an antireflection film on a surface thereof and a method of manufacturing the optical member.

2. Description of the Related Art

Conventionally, lenses (transparent substrates) made of a light-transmitting member, such as glass or plastic, are provided on the light entrance surface thereof with an antireflection structure (antireflection film) for reducing loss of the transmitted light due to surface reflection.

For example, as antireflection structures for visible light, a dielectric multi-layer film, a fine uneven structure having a pitch shorter than the wavelength of visible light, etc., are known (see, for example, Japanese Unexamined Patent Publication Nos. 2005-275372 and 2010-066704, which will hereinafter be referred to as Patent Literature 1 and 2, respectively).

A fine uneven structure provided on a lens surface has a gradient refractive index that gradually changes from a refractive index close to the refractive index of the lens to a refractive index close to the refractive index of air, thereby mitigating the difference between the refractive index of the lens and the refractive index of air to prevent reflection of incident light.

Patent Literature 1 discloses an arrangement where a fine uneven layer is formed on a substrate via a transparent thin film layer. The fine uneven layer is mainly composed of alumina, and the transparent thin film layer contains at least one of zirconia, silica, titania, and zinc oxide. Patent Literature 1 teaches that the uneven layer and the underlying transparent thin film layer are obtained by forming a multi-component film using a coating solution that at least contains an aluminum compound and a compound of at least one of zirconia, silica, titania, and zinc oxide, and performing a hot water treatment on the multi-component film.

Patent Literature 2 discloses an arrangement where a fine uneven layer mainly composed of alumina is formed on a substrate via Al₂O₃ and SiO₂. Patent Literature 2 teaches that, as a method for growing boehmite, which is a hydroxide of aluminum, on a light-transmitting substrate, a method including forming an alumina film by vacuum deposition or a sol-gel method, and performing a steam treatment or a hot water treatment on the alumina film is used; however, Patent Literature 2 does not clearly describe the actual method used.

### SUMMARY OF THE INVENTION

Patent Literature 1 teaches that the thickness of the fine uneven film can be controlled to be in the range from 0.005 to 5.0 μm, and the thickness of the transparent layer can be controlled to be in the range from 0.01 to 10 μm. It is assumed in Patent Literature 1 that a sol-gel method is used to form the multi-component film. However, sol-gel methods cannot be performed in batch processing and has a problem of low productivity.

Patent Literature 2 teaches that Al₂O₃ having a thickness of 80 nm and SiO₂ having a thickness of 100 nm are formed in this order on a substrate by evaporation, and then a fine uneven thin film mainly composed of alumina having a thickness of 300 nm is formed. However, as mentioned previously, Patent Literature 2 does not disclose the specific method for forming the uneven thin film.

In a case where an antireflection film is formed on a substrate having a refractive index higher than that of Al₂O₃ (n=1.67), it is desirable to provide a layer having a refractive index higher than that of Al₂O₃ on the substrate side of the antireflection film. In this case, an arrangement may be contemplated where the layer structure taught in Patent Literature 2 is further provided with a layer made of a material (TiO₂, for example) having a refractive index higher than that of Al₂O₃. In this case, however, at least three materials (Al₂O₃, SiO₂, TiO₂) are necessary and the number of evaporation hearths or the number of targets required for forming the films are necessary, resulting in a very complicated production method.

In view of the above-described circumstances, the present invention is directed to providing an optical member provided with an antireflection film that can be formed by a simpler method using fewer materials, and a method of manufacturing the optical member.

An optical member of the invention is an optical member with an antireflection film,

the antireflection film comprising a transparent thin film layer, and a transparent fine uneven layer whose main component is an alumina hydrate, which layers are formed in this order on a surface of a transparent substrate,

wherein the transparent thin film layer has an intermediate refractive index between a refractive index of the transparent substrate and a refractive index of the fine uneven layer, and

the transparent thin film layer comprises at least a nitride layer or an oxynitride layer.

The “main component” as used herein is defined as a component whose content in weight % is the largest among components of a chemical structure contained in the relevant part.

In the above, the refractive index of the transparent thin film layer and the refractive index of the fine uneven layer refer to an average refractive index of each layer.

It is preferred that the transparent thin film layer comprise a plurality of nitride layers and/or oxynitride layers of the same constituent element, and a layer of the plurality of layers closer to the transparent substrate have a higher nitrogen content than a nitrogen content of a layer of the plurality of layers closer to the fine uneven layer.

The expression “the same constituent element” in “comprises a plurality of nitride layers and/or oxynitride layers of the same constituent element” refers to that the constituent element (such as a metal, a non-metal, or an alloy) which is nitrided or oxynitrided is the same among the layers. Therefore the nitride layers and/or oxynitride layers of the same constituent element are SiN and/or SiON if the nitrided constituent element is Si, AlN and/or AlON if the nitrided constituent element is Al, and SiAlN and/or SiAlON if the nitrided constituent elements are SIAl, for example. Further, the expression “comprises a plurality of nitride layers and/or oxynitride layers” may refer to comprising a plurality of layers including only nitride layers, a plurality of layers including only oxynitride layers, or a plurality of layers including nitride layers and oxynitride layers.

It is preferred that the nitride layer be made of SiN, AlN, or SiAlN, and the oxynitride layer be made of SiON, AlON, or SiAlON.

It is preferred that the transparent thin film layer comprise a flat layer whose main component is an alumina hydrate located next to the fine uneven layer.

In this case, the fine uneven layer may have a thickness of 150 nm or less.

It is preferred that, when the surface of the transparent substrate is a curved surface where an angle between lines normal to the opposite ends of the curved surface exceeds 90°, the transparent thin film layer have a thickness of at least 274 nm at the center of the curved surface.

The transparent thin film layer may be formed by reactive sputtering.

A method of manufacturing the optical member of the invention is a method of manufacturing an optical member with an antireflection film, the antireflection film comprising a transparent thin film layer, and a transparent fine uneven layer whose main component is an alumina hydrate, which layers are formed in this order on a surface of a transparent substrate, the method comprising:

forming, on the transparent substrate, at least one of a nitride layer and an oxynitride layer, and an alumina layer in this order by reactive sputtering; and

performing a hot water treatment on the transparent substrate with at least one of the nitride layer and the oxynitride layer, and the alumina layer formed thereon.

The optical member of the invention includes a transparent thin film layer, and a transparent fine uneven layer whose main component is an alumina hydrate, which are formed in this order on a surface of a transparent substrate, and the optical member includes at least a nitride layer or an oxynitride layer as the transparent thin film layer having an intermediate refractive index between the refractive index of the transparent substrate and the refractive index of the fine uneven layer. Use of a nitride allows providing a refractive index higher than that of an oxide layer, and this allows significantly increasing choices of the layer disposed between the transparent substrate and the fine uneven layer.

In the case where the optical member of the invention includes a plurality of nitride layers and/or oxynitride layers of the same constituent element, the refractive indices of the layers can be controlled by changing the amount of nitridation by using vapor deposition, which allows batch processing to achieve high productivity, and this allows forming the layers using fewer materials.

### BRIEF DESCRIPTION OF THE DRAWINGS

FIG. 1 is a schematic sectional view illustrating the schematic structure of an optical member of a first embodiment,

FIG. 2 is a schematic sectional view illustrating the schematic structure of an optical member of modification 1,

FIG. 3 is a schematic sectional view illustrating the schematic structure of an optical member of modification 2,

FIG. 4 shows a SEM image of a fine uneven layer in plain view,

FIG. 5 shows a SEM image of the fine uneven layer in sectional view,

FIG. 6 shows the relationship among the thickness of an Al film formed, and the thicknesses of the uneven layer and a flat layer,

FIG. 7 shows the refractive index of the fine uneven layer and the flat layer,

FIG. 8A is a schematic diagram of the fine uneven layer,

FIG. 8B is a reference diagram for illustrating the dependency of the refractive index of the fine uneven structure on the height,

FIG. 9 is a schematic sectional view illustrating the schematic structure of an optical member of a second embodiment,

FIG. 10 is a diagram for explaining a deposition angle φ,

FIG. 11 shows the dependency of the reflectance on the wavelength for each deposition angle φ with reduced film thickness at the peripheral portion of a curved surface,

FIG. 12 shows the dependency of the reflectance on the wavelength for each deposition angle φ of an optical member of Example 1,

FIG. 13 shows the dependency of the reflectance on the wavelength for each deposition angle φ of an optical member of Example 2,

FIG. 14 shows the dependency of the sum of reflectance on the film thickness of SiO₂ of Comparative Example 1, and

FIG. 15 shows the dependency of the reflectance on the wavelength of an optical member of Comparative Example 1 where the film thickness of SiO₂ is 100 nm.

### DETAILED DESCRIPTION OF THE PREFERRED EMBODIMENTS

Hereinafter, embodiments of the present invention will be described with reference to the drawings.

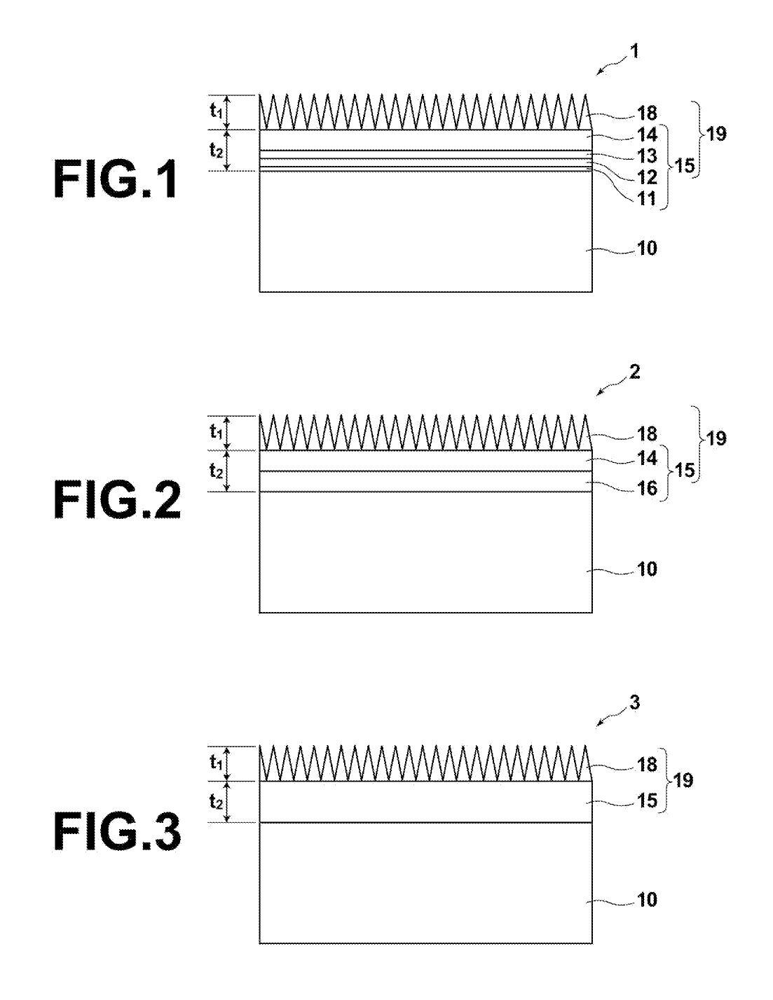

FIG. 1 is a schematic sectional view illustrating the structure of an optical member 1 of a first embodiment of the invention.

The optical member 1 of the first embodiment includes an antireflection film 19 formed on a surface of a transparent substrate 10, and the antireflection film 19 includes a transparent thin film layer 15, and a transparent fine uneven layer 18 whose main component is an alumina hydrate which are formed in this order on the transparent substrate 10. The transparent thin film layer 15 includes a nitride layer 11, oxynitride layers 12 and 13, and a transparent flat layer 14 whose main component is an alumina hydrate. The transparent thin film layer 15 has a refractive index which is an intermediate value of the refractive index of the transparent substrate 10 and the refractive index of the fine uneven layer 18, where the relationship among a refractive index n₀ of the transparent substrate 10, a refractive index n₁ of the nitride layer 11, a refractive index n₂ of the oxynitride layer 12, a refractive index n₃ of the oxynitride layer 13, a refractive index n₄ of the flat layer 14, and a refractive index n₅ of the uneven layer 18 is n₀>n₁>n₂>n₃>n₄>n₅, and the refractive index of the transparent thin film layer 15 gradually decreases from a refractive index close to the refractive index of the transparent substrate 10, such as a lens, to a refractive index close to the refractive index of air. The refractive index n₅ of the uneven layer in the above inequality is an average refractive index of the entire uneven layer 18.

In a case where the nitride layer 11, and the oxynitride layers 12 and 13 are made of a nitride and oxynitrides of the same material, a higher refractive index can be provided at a portion closer to the transparent substrate by setting the nitrogen content such that a portion closer to the transparent substrate 10 has a higher nitrogen content.

Although the transparent thin film layer 15 in this embodiment has a four-layer structure, the transparent thin film layer 15 may be a single layer or any number of layers, such as two or more layers. In a case where the transparent thin film layer 15 is formed by a plurality of layers, the layers may be disposed such that a layer closer to the substrate has a higher refractive index. It is preferred that a total film thickness t₂ of the transparent thin film layer 15 be at least 150 nm.

The transparent thin film layer 15 may have a two-layer structure including one nitride layer or oxynitride layer 16, and the flat layer 14 whose main component is an alumina hydrate, as in an optical member 2 of a modification shown in FIG. 2, or may be a single layer formed by a nitride layer or oxynitride layer, as in an optical member 3 of another modification shown in FIG. 3.

Specific examples of the nitride include nitrides of Si, Al, and SiAl, namely, SiN, AlN, and SiAlN.

Specific examples of the oxynitride include oxynitrides of Si, Al, and SiAl, namely, SiON, AlON, and SiAlON.

The nitride and oxynitride of each material have a higher refractive index when they have a higher nitrogen content.

The nitride layer and/or oxynitride layer of the same constituent element is a nitride layer and/or oxynitride layer of Si, Al, or SiAl, for example. The nitride layer and/or oxynitride layer of Si may be a layer of SiN, a layer of SiON, or layers of SiN and SiON. When only a SiN layer is provided as the nitride layer, the SiN layer may include a plurality of layers having different nitrogen contents. The refractive index of the nitride and oxynitride of the same constituent element can be changed only by changing the nitrogen content.

Examples of the alumina hydrate include boehmite (which is written as Al₂O₃.H₂O or AlOOH), which is alumina monohydrate, bayerite (which is written as Al₂O₃.3H₂O or Al(OH)₃), which is alumina trihydrate (aluminum hydroxide), etc.

The fine uneven layer 18 whose main component is an alumina hydrate is transparent, and has a substantially saw tooth-like cross-section, as shown in FIG. 1, etc., where the size (the magnitude of apex angle) and the orientation vary, though. The pitch (average pitch) of the fine uneven layer 18 is sufficiently smaller than the shortest wavelength in the wavelength range used, which is the wavelength range of the incoming light. The pitch of the fine uneven layer 18 refers to a distance between the apices of adjacent protrusions of the fine uneven structure with a recess therebetween, and the depth of the fine uneven layer 18 refers to a distance from the apices of protrusions to the bottoms of their adjacent recesses of the fine uneven structure.

The pitch of the fine uneven structure is on the order of several tens nanometers to several hundreds nanometers.

Further, an average depth (film thickness of the uneven layer) t₁ from the apices of the protrusions to the bottoms of their adjacent recesses in this embodiment is 150 nm or less.

The structure of the fine uneven layer 18 is such that the structure is more sparse (i.e., the widths of voids which are equivalent to the recesses are larger and the widths of the protrusions are smaller) at a position farther away from the substrate, and the refractive index is lower at a position farther away from the substrate.

The average pitch of the uneven structure is found by taking a surface image of the fine uneven structure with a SEM (scanning electron microscope), binarizing the surface image by applying image processing, and applying statistical processing. Similarly, the film thickness of the uneven layer is found by taking a cross-section image of the fine uneven layer, and applying image processing.

The fine uneven layer can be formed by forming an alumina or aluminum film, and then performing a hot water treatment on the formed film. The alumina or aluminum film can be formed by batch processing to improve the productivity, and it is preferred to use a vapor deposition method such as evaporation or sputtering. The present inventors have found through a study that, when evaporation or sputtering is used, the fine uneven layer can be formed by forming an aluminum film having a predetermined thickness and then performing a hot water treatment; however, the thickness of the thus formed fine uneven layer is up to around 150 nm and a greater thickness cannot be obtained even when the thickness of the aluminum formed is changed. Under the fine uneven layer, a layer (flat layer) whose main component is an alumina hydrate and whose refractive index is almost uniform in the thickness direction is formed.

Now, our study about the fine uneven layer is described.

An Al film was formed by sputtering on a glass substrate (EAGLE 2000, available from Corning Incorporated), and then immersed in boiling water for five minutes as the hot water treatment to form on the surface a fine uneven layer whose main component is an alumina hydrate.

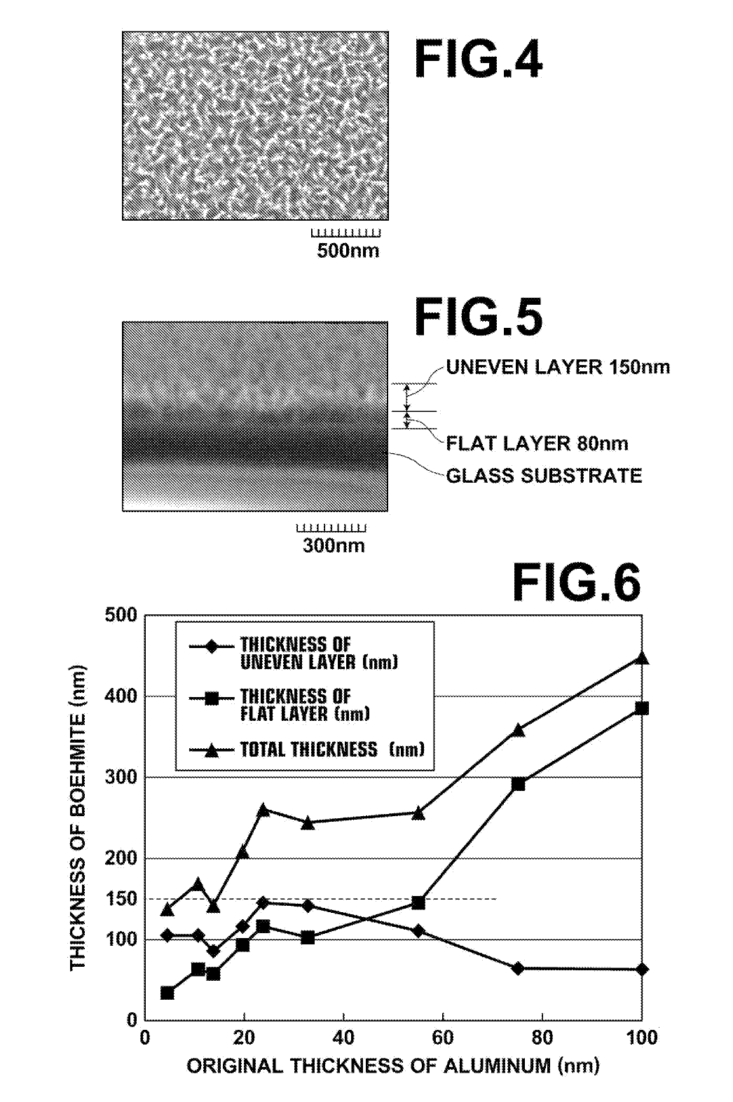

FIG. 4 shows a SEM image of the thus made fine uneven layer in plain view, and FIG. 5 shows a SEM image of the fine uneven layer in sectional view.

As shown in FIG. 5, the fine uneven layer was formed on the surface, and the flat layer was formed between the substrate and the uneven layer.

Changing the thickness of the Al film formed and performing the same hot water treatment, the relationship among the thickness of the Al film before immersion and the thicknesses of the fine uneven layer and the flat layer was examined, and the results are shown in FIG. 6.

As shown in FIG. 6, it was found that the thickness of the fine uneven layer is 150 nm or less even when the thickness of the Al film formed is increased. Although the cases where an Al film was formed and subjected to the hot water treatment to form boehmite are shown in FIG. 6, similar data was obtained in cases where an Al₂O₃ film was formed in place of Al and subjected to the hot water treatment to form boehmite. Also, similar data was obtained when evaporation was used in place of sputtering to form an Al film.

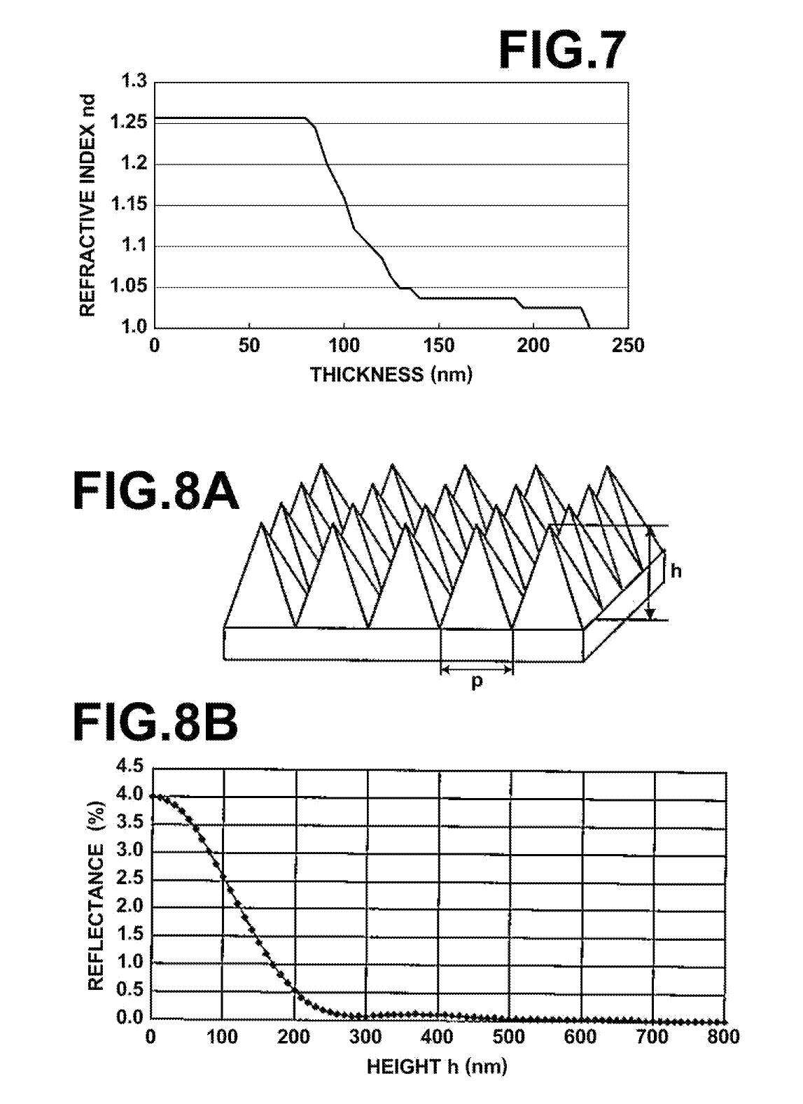

Further, the refractive index of a boehmite layer (the fine uneven layer and the flat layer), which was formed by forming an Al₂O₃ film having a thickness of 30 nm on Si and performing the hot water treatment, was measured with a spectroscopic ellipsometer, and the obtained results are shown in FIG. 7. In FIG. 7, the thickness of 0 corresponds to the surface position of the substrate, and the thickness of 230 nm where the refractive index is 1 corresponds to the surface position of the uneven structure layer.

As shown in FIG. 7, the refractive index nd of the flat layer had a constant value of 1.26, and the flat layer had a thickness of about 80 nm. The refractive index of the uneven layer was such that a portion of the uneven layer farther away from the substrate had a lower effective refractive index, and the uneven layer had a thickness of 150 nm. The total film thickness was 230 nm.

FIGS. 8A and 8B are figures included in D. Sano, “Development of high performance anti-reflective coating “SWC” with sub-wavelength structures”, the 123rd Microoptics Group MICROOPTICS NEWS, Vol. 30, No. 1, pp. 47-52, 2012, which are reference diagrams for illustrating the dependency of the refractive index of the fine uneven structure on the height. In a case where a substrate having a refractive index of 1.5 is used, a necessary height h of the fine uneven structure, which is assumed to be a quadrangular-pyramids structure (FIG. 8A shows the schematic diagram thereof), for obtaining a sufficiently low reflectance is h=300 nm or more, as shown in FIG. 8B. In a case where a substrate having a refractive index higher than 1.5 is used, it is necessary to increase the height of the quadrangular pyramids.

However, the fine uneven layer obtained after the hot water treatment of the film formed by sputtering has a thickness of 150 nm or less, as described above, and this is not sufficient for providing a sufficient antireflection effect. To address this problem, a transparent thin film layer having an intermediate refractive index between the refractive indices of the fine uneven structure and the substrate is provided between the fine uneven structure and the substrate.

At this time, forming the above-described transparent thin film layer including a nitride layer or oxynitride layer of Al or Si by a vapor deposition method, such as reactive sputtering or evaporation, allows batch processing, and allows minimizing the number of sputtering targets, or the number of evaporation hearths.

In particular, when reactive sputtering is used, layers having various refractive indices can be formed very easily by using only two targets of Si and Al and controlling the flow ratio of N₂ to O₂, which are reactive gasses.

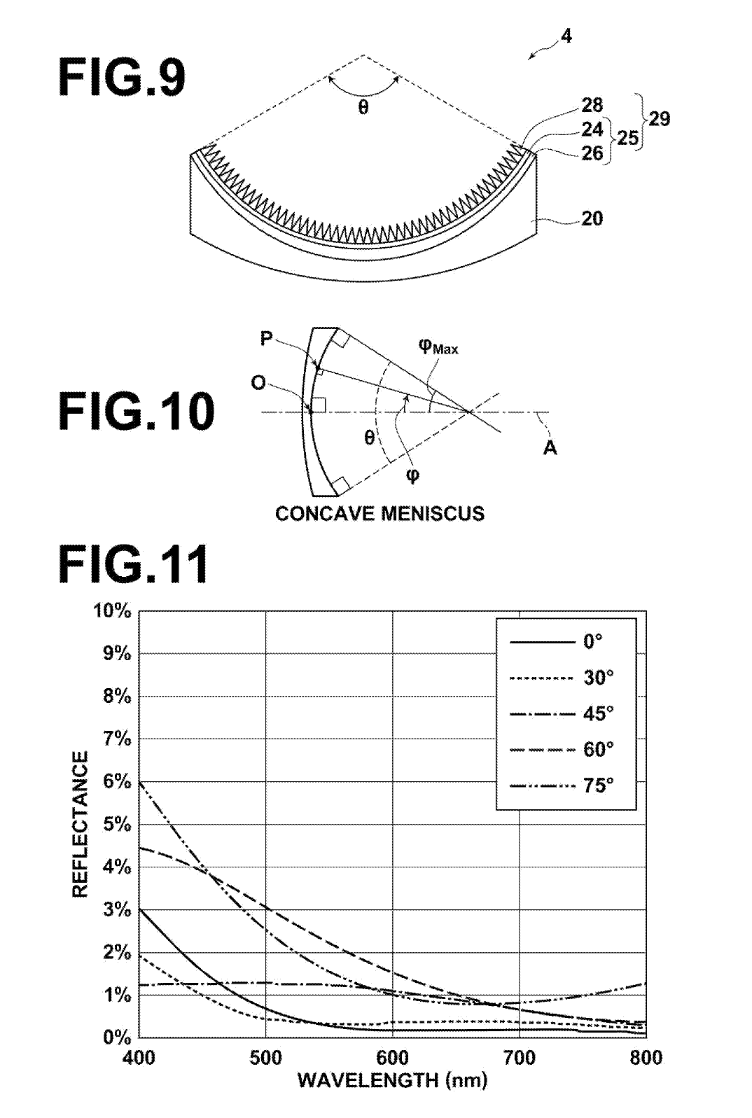

FIG. 9 is a schematic sectional view illustrating the structure of an optical member 4 of a second embodiment of the invention. As shown in FIG. 9, the optical member 4 includes: a meniscus lens with curved surfaces as the transparent substrate 20; and an antireflection film 29 formed on the concave surface of the meniscus lens, the antireflection film 29 including a transparent thin film layer 25, and a transparent fine uneven layer 28 whose main component is an alumina hydrate, which are formed in this order on the concave surface. The transparent thin film layer 25 includes, in order from the substrate 20 side, a nitride layer or oxynitride layer 26, and a flat layer 24 whose main component is an alumina hydrate.

It should be noted that the transparent thin film layer 25 may include a plurality of oxide layers or oxynitride layers. Details of this case are similar to those described in the first embodiment.

It is particularly preferred that the curved surface (concave surface) of the transparent substrate 20 is such that an angle θ between lines normal to the opposite ends of the curved surface, which is cut as the effective optical surface of the lens, exceeds 90°.

In the case where the surface on which the antireflection film 29 is formed is a curved surface, as in this embodiment, forming the antireflection film 29 by evaporation or sputtering results in a film having the largest film thickness at the center portion of the curved surface and a smaller film thickness at a portion closer to the peripheral portion. FIG. 10 is a diagram for explaining a deposition angle φ for forming the thin film layer on the curved surface of the concave surface of a meniscus lens. During the film formation, the evaporation source or sputtering target is disposed to face the lens at a position along a line A normal to the center O of the lens. It is assumed here that the evaporation source or sputtering target is a point source. The deposition angle φ is defined as an angle between the normal line A and a line normal to each position P on the lens surface. According to this definition, the deposition angle φ for the center position O of the lens surface is 0°, and the deposition angle φ for the end positions of the curved surface is a maximum deposition angle φ_{Max}. It should be noted that θ is twice the maximum deposition angle φ_{Max}. The number of particles incident on each surface position is proportional to cos φ of the deposition angle φ during evaporation or sputtering. That is, the film thickness at the peripheral portion of the lens is smaller than the film thickness at the center position of the lens.

The present inventors have found through a study that, if the surface of the transparent substrate is such a curved surface that the angle θ between the normal lines exceeds 90°, the thickness of the transparent thin film layer at the center of the transparent substrate is preferably at least 274 nm to obtain a sufficient antireflection effect.

With respect to a lens (OHARA S-LAH58), each evaporation source was set at the angle of 0°, i.e., along the line normal to the center of the lens surface, and an Al₂O₃ film having a thickness of 100 nm, a SiO₂ film having a thickness of 40 nm, and an Al₂O₃ film having a thickness of 30 nm were formed in this order by evaporation. Then, a hot water treatment was performed to convert the uppermost Al₂O₃ layer into a flat boehmite layer having a thickness of 80 nm, and an uneven boehmite layer having a thickness of 150 nm. FIG. 11 shows data of the reflectance relative to the angle in this case. The reflectance significantly increases at positions where the angle is larger than φ=45°. The reason is believed that, even when the total film thickness is 290 nm at the position corresponding to the angle φ=0°, the film thickness decreases as the angle φ increases, and the influence is significant at positions where the angle exceeds 45°. This experiment clearly demonstrates that a larger deposition angle φ during the film formation on the curved surface results in a smaller thickness of the formed film.

Conditions for ensuring a total thickness of at least 300 nm of the transparent thin film layer and the fine uneven layer at the peripheral portion of the lens have been studied.

Table 1 shows the total thickness (Total (φ=0), t[nm]) and the thickness of the transparent thin film layer (Total (φ=0), t-150[nm]) that are necessary at the position corresponding to the deposition angle of 0° for ensuring a thickness of at least 300 nm at a position corresponding to each deposition angle φ.

TABLE 1

| | | | Total (φ = 0) | Total (φ = 0) |
|---|---|---|---|---|
| φ | Cosφ | 1/Cosφ | t [nm] | t − 150 [nm] |
| 0 | 1.000 | 1 | 300 | 150 |
| 5 | 0.996 | 1.00 | 301 | 151 |
| 10 | 0.985 | 1.02 | 305 | 155 |
| 15 | 0.966 | 1.04 | 311 | 161 |
| 20 | 0.940 | 1.06 | 319 | 169 |
| 25 | 0.906 | 1.10 | 331 | 181 |
| 30 | 0.866 | 1.15 | 346 | 196 |
| 35 | 0.819 | 1.22 | 366 | 216 |
| 40 | 0.766 | 1.31 | 392 | 242 |
| 45 | 0.707 | 1.41 | 424 | 274 |
| 50 | 0.643 | 1.56 | 467 | 317 |
| 55 | 0.574 | 1.74 | 523 | 373 |
| 60 | 0.500 | 2.00 | 600 | 450 |
| 65 | 0.423 | 2.37 | 710 | 560 |
| 70 | 0.342 | 2.92 | 877 | 727 |
| 75 | 0.259 | 3.86 | 1159 | 1009 |
| 80 | 0.174 | 5.76 | 1728 | 1578 |
| 85 | 0.087 | 11.47 | 3442 | 3292 |

As shown in Table 1, in order to ensure a layer thickness of at least 300 nm at the position corresponding to φ=45°, it is necessary to set a total thickness of 424 nm at the position corresponding to φ=0° and, since the fine uneven layer has a thickness of 150 nm or less, the transparent thin film needs to have a thickness of at least 274 nm. Also, in order to ensure a layer thickness of at least 300 nm at the position corresponding to φ=85°, it is necessary to set a total thickness of 3442 nm at the position corresponding to q=0° and, since the fine uneven layer has a thickness of 150 nm or less, the transparent thin film layer needs to have a thickness of at least 3292 nm.

It should be noted that, if the transparent film is excessively thick, the thin film tends to be broken due to the film stress. Further, it takes time to form the film, leading to cost increase. Accordingly, the transparent film having an excessive thickness is not preferred. It is therefore desirable that the thickness of the transparent thin film layer at the position corresponding to φ=0° is controlled to be the minimum thickness that can ensure a layer thickness of at least 300 nm at the surface position corresponding to the maximum deposition angle φ_{Max} (=θ/2) of a lens having a curved surface with a desired θ.

### EXAMPLES

### Example 1

Using an ECR (electron cyclotron resonance) sputtering apparatus, a first SiON layer, a second SiON layer, a SiO₂ layer, and an Al₂O₃ layer were formed in this order on a curved lens surface having a radius of curvature of 36.4 mm of a glass material OHARA S-LAH58 (having a refractive index nd=1.88300) with a maximum deposition angle φ_{Max}=62.5°. At this time, each layer was formed by ECR sputtering using Si and Al targets, respectively, with controlling the flow ratio of N₂ to O₂.

The first SiON layer (nd=1.75) had a film thickness of 80 nm, the second SiON layer (nd=1.61) had a film thickness of 80 nm, the SiO₂ layer (nd=1.48) had a film thickness of 80 nm, and the Al₂O₃ layer had a film thickness of 30 nm. It should be noted that the film thickness here refers to the film thickness at the center portion of the lens, which is the largest thickness.

After the uppermost Al₂O₃ layer was formed, a hot water treatment was performed by immersing the layers in boiling water for five minutes. Through the hot water treatment, the uppermost Al₂O₃ layer was converted into a boehmite layer (flat layer) having a film thickness of 80 nm and a refractive index nd=1.26, and a uneven boehmite layer (fine uneven layer) having a film thickness of 150 nm.

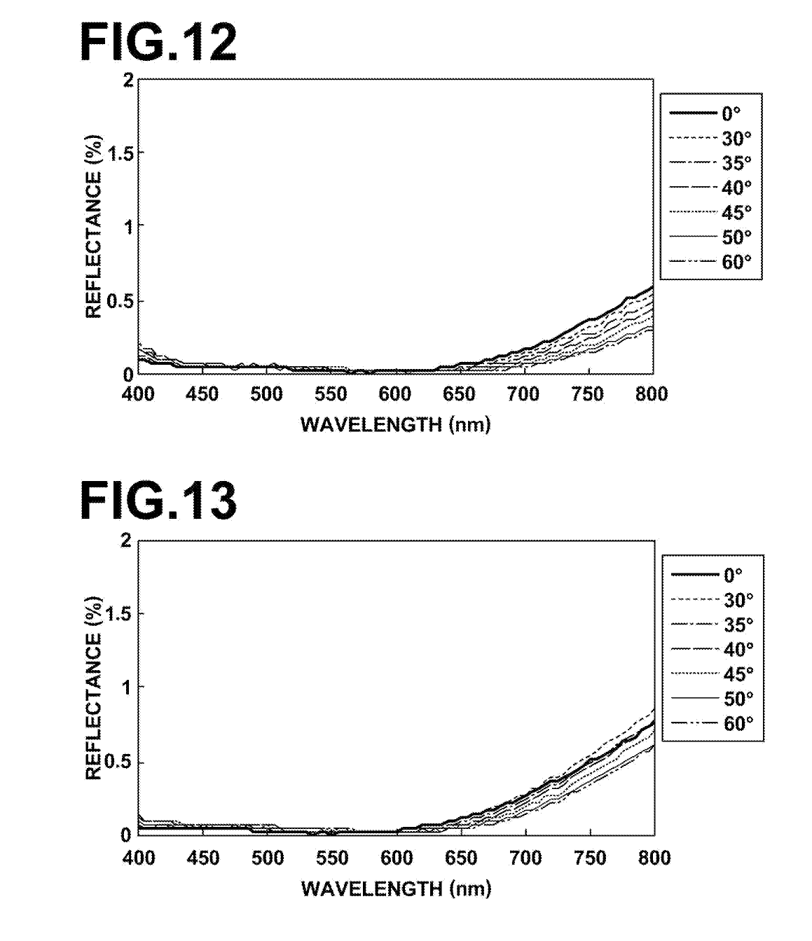

The reflectance of the lens was measured using a spectroscopic measurement apparatus FE-3000, available from Otsuka Electronics Co., Ltd. The results are shown in FIG. 12. As shown in FIG. 12, the optical member of this example achieved low reflectance throughout the wavelength range from 400 to 800 nm with the maximum reflectance being around 0.5%.

### Example 2

Using an ECR (electron cyclotron resonance) sputtering apparatus, an AIN layer, an AlON layer, a SiN layer, a first SiON layer, a second SiON layer, a SiO₂ layer, and an Al₂O₃ layer were formed in this order on a curved lens surface having a radius of curvature of 36.4 mm of a glass material OHARA S-LAH58 (having a refractive index nd=1.88300) with a maximum deposition angle φ_{Max}=62.5°. At this time, each layer was formed by ECR sputtering using Si and Al targets, respectively, with controlling the flow ratio of N₂ to O₂.

The AIN layer (nd=2.01) had a film thickness of 40 nm, the AlON layer (refractive index nd=1.95) had a film thickness of 40 nm, the SiN layer (nd=1.91) had a film thickness of 40 nm, the first SiON layer (nd=1.64) had a film thickness of 40 nm, the second SiON layer (nd=1.55) had a film thickness of 40 nm, the SiO₂ layer (nd=1.46) had a film thickness of 40 nm, and the Al₂O₃ layer had a film thickness of 30 nm.

After the uppermost Al₂O₃ layer was formed, a hot water treatment was performed by immersing the layers in boiling water for five minutes. Through the hot water treatment, the uppermost Al₂O₃ layer was converted into a boehmite layer (flat layer) having a film thickness of 80 nm and a refractive index nd=1.26, and a uneven boehmite layer (fine uneven layer) having a film thickness of 150 nm.

The reflectance of the lens was measured using a spectroscopic measurement apparatus FE-3000, available from Otsuka Electronics Co., Ltd. The results are shown in FIG. 13. As shown in FIG. 13, the optical member of this example achieved low reflectance of 1% or less throughout the wavelength range from 400 to 800 nm.

### Comparative Example 1

Using an EB (electron beam) vapor deposition apparatus, a SiO₂ layer and an Al₂O₃ layer were formed in this order on a curved lens surface having a radius of curvature of 36.4 mm of a glass material OHARA S-LAH58 (having a refractive index nd=1.88300) with a maximum deposition angle φ_{Max}=62.5°.

The Al₂O₃ layer had a film thickness of 30 nm. After the Al₂O₃ layer was formed, a hot water treatment was performed by immersing the layers in boiling water for five minutes. Through the hot water treatment, the uppermost Al₂O₃ layer was converted into a boehmite layer (flat layer) having a film thickness of 80 nm and a refractive index nd=1.26, and a uneven boehmite layer (fine uneven layer) having a film thickness of 150 nm.

For each sample prepared by changing the film thickness of the SiO₂ layer (nd=1.46) from 0 to 160 nm at an increment of 10 nm, a sum of reflectances for incoming light of different wavelengths from 450 to 700 nm at an increment of 10 nm was examined. The reflectance of each lens was measured using a spectroscopic measurement apparatus FE-3000, available from Otsuka Electronics Co., Ltd.

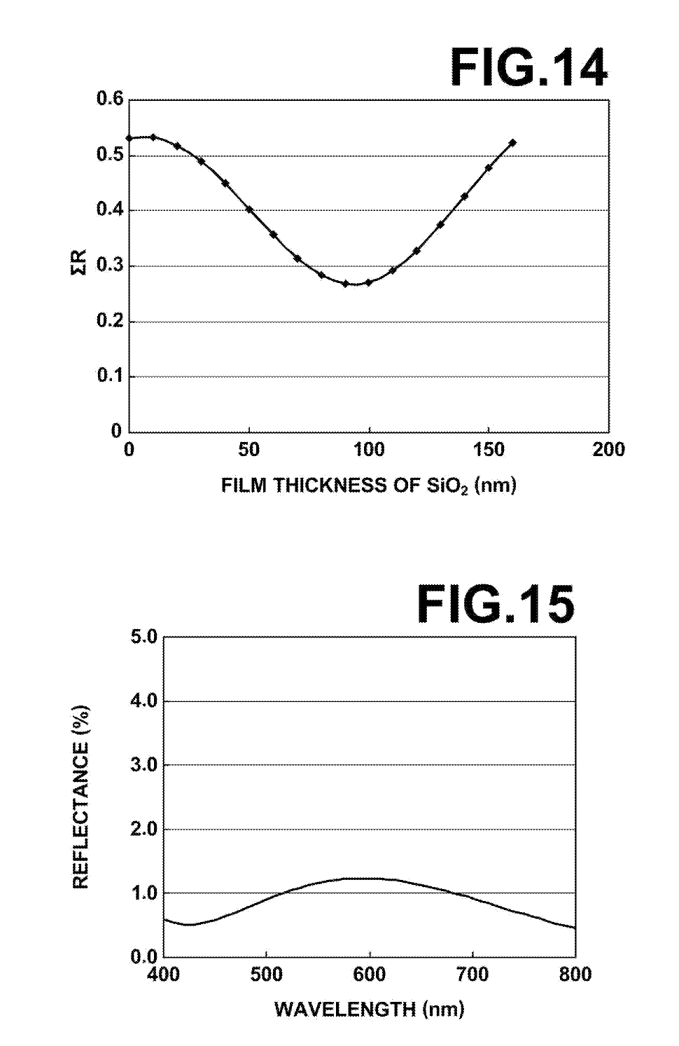

The results are shown in FIG. 14. As shown in FIG. 14, the sum of the reflectances was the smallest when the film thickness of the SiO₂ layer was around 100 nm. However, as can be seen from the spectrum shown in FIG. 15 of the case where the film thickness of the SiO₂ layer was 100 nm, the reflectance of the optical member of this arrangement for light of a wavelength in the range from 520 to 680 nm exceeded 1.0%.

What is claimed is:

1. An optical member with an antireflection film,
the antireflection film comprising a transparent thin film layer, and a transparent fine uneven layer whose main component is an alumina hydrate, which layers are formed in this order on a surface of a transparent substrate,
wherein the transparent thin film layer has an intermediate refractive index between a refractive index of the transparent substrate and a refractive index of the fine uneven layer, and
the transparent thin film layer comprises at least a nitride layer or an oxynitride layer.

2. The optical member as claimed in claim 1, wherein the transparent thin film layer comprises a plurality of nitride layers and/or oxynitride layers of the same constituent element, and a layer of the plurality of layers closer to the transparent substrate has a higher nitrogen content than a nitrogen content of a layer of the plurality of layers closer to the fine uneven layer.

3. The optical member as claimed in claim 1, wherein the nitride layer is made of SiN, AlN, or SiAlN, and the oxynitride layer is made of SiON, AlON, or SiAlON.

4. The optical member as claimed in claim 1, wherein the transparent thin film layer comprises a flat layer whose main component is an alumina hydrate located next to the fine uneven layer.

5. The optical member as claimed in claim 1, wherein the fine uneven layer has a thickness of 150 nm or less.

6. The optical member as claimed in claim 5, wherein
the surface of the transparent substrate is a curved surface where an angle between lines normal to the opposite ends of the curved surface exceeds 90°, and
the transparent thin film layer has a thickness of at least 274 nm.

7. The optical member as claimed in claim 1, wherein the transparent thin film layer is formed by reactive sputtering.

8. A method of manufacturing an optical member with an antireflection film, the antireflection film comprising a transparent thin film layer, and a transparent fine uneven layer whose main component is an alumina hydrate, which layers are formed in this order on a surface of a transparent substrate, the method comprising:
forming, on the transparent substrate, at least one of a nitride layer and an oxynitride layer, and an alumina layer in this order by reactive sputtering; and
performing a hot water treatment on the transparent substrate with at least one of the nitride layer and the oxynitride layer, and the alumina layer formed thereon.
